(19) United States
(12) Patent Application Publication
(10) Pub. No.: US 2010/0244105 A1
(43) Pub. Date: Sep. 30, 2010

(54) TRANSISTORS HAVING TEMPERATURE STABLE SCHOTTKY CONTACT METALS

(76) Inventor: Kiuchul Hwang, Amherst, NH (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(21) Appl. No.: 12/414,944

(22) Filed: Mar. 31, 2009

(51) Int. Cl. H01L 29/812; H01L 23/498

(52) U.S. Cl. 257/280; 257/745; 257/E23.072; 257/E29.317

(57) ABSTRACT

A semiconductor structure having: a semiconductor comprising a indium gallium phosphide and molybdenum metal in Schottky contact with the semiconductor.

### TECHNICAL FIELD

This invention relates generally to transistors and more particularly to transistors having Schottky contact metals.

### BACKGROUND

As is known in the art, Schottky metals have been used to provide transistor gate contacts. As is also known in the art, InGaP semiconductors have been used to provide active regions for transistors, such as for High Electron Mobility Transistor (HEMT) devices, and metals such as Ti, Pt and Au have been used as Schottky metals contacts to such active regions to provide gate electrodes for the transistors. These Ti, Pt and Au metals however react with indium in the compound semiconductors when the transistors are exposed to high temperature above 200 degrees C. This reaction causes the threshold voltage (Vth) of the transistors to shift about 0.5 to 1.0 V. This temperature unstable threshold voltage variation precludes use of such a transistor from many HEMT applications.

### SUMMARY

In accordance with the present invention, a semiconductor structure is provided comprising: a semiconductor comprising indium gallium phosphide; and a molybdenum

In one embodiment, the structure includes an electrically conductive metal on the molybdenum metal.

In one embodiment, the electrically conductive metal comprises titanium on the molybdenum metal, platinum on the titanium, and gold on the platinum.

In one embodiment, the molybdenum metal provides a gate electrode for a transistor.

With such an arrangement, a metal layer structure is provided for a device wherein the threshold voltage of the device is stable and does not vary significantly at high temperature.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a semiconductors structure according to the invention;

FIG. 2A are curves showing Transconductance (Gm) and Drain to Source Current (IDS) as a function of VGS for a FET having an InGaP active gate layer and a 500 Angstrom thick titanium metal Schottky contact to such active layer prior to and subsequent to a 300 degree C. anneal;

FIGS. 2B-2D are curves showing Gm and IDS as a function of VGS for a FET having an InGaP active gate layer and a 70, 50 and 30 Angstrom thick platinum metal Schottky contacts, respectively, to such active layer prior to and subsequent to a 300 degree C. anneal;

FIG. 3 are curves showing the change in Gm and change in threshold voltage as a function of platinum thick, such curves being obtained from the data in FIGS. 2B-2D.

FIGS. 4A and 4B are curves showing Gm and IDS of the semiconductor structure of FIG. 1 as a function of VGS for a FET having an InGaP active gate layer and a 30 and 50 Angstrom thick, respectively, molybdenum metal Schottky contact to such active layer prior to and subsequent to a 300 degree C. anneal;

Like reference symbols in the various drawings indicate like elements.

### DETAILED DESCRIPTION

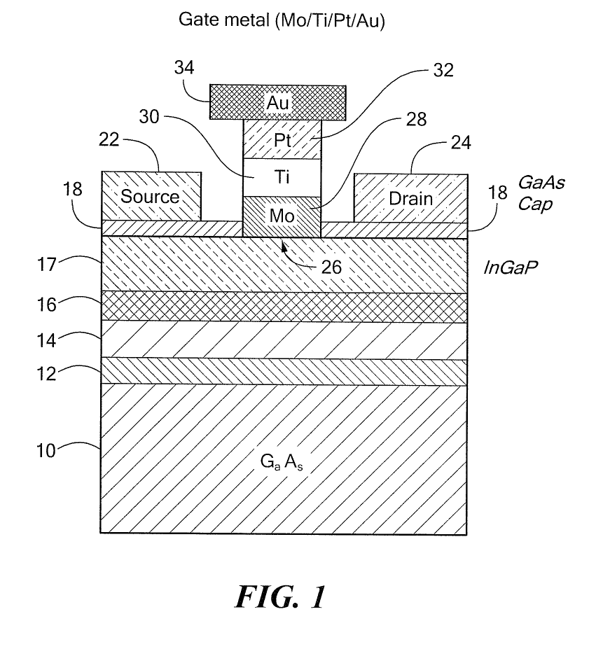

Referring now to FIG. 1, a semiconductor structure 10 is shown. Here the structure is a field effect transistor (FET). The structure 10 includes a III-V substrate, here a GaAs substrate, a layer 12 of AlGaAs on the substrate 10, a layer 14 of GaAs on layer 12, a layer 16 of AlGaAs on layer 14 and an active semiconductor layer 17, here InGaP on layer 16.

A layer 18 of GaAs is formed on the on the active semiconductor layer 17. Source and drain ohmic contacts 22, 24 are formed on the GaAs layer 18, as shown. here, the source and drain ohmic contacts are, for example, Au (gold)/Ge (Germanium) and are alloyed with the GaAs layer 18 in any conventional manner.

Next, a portion of the active semiconductor layer 18 is etched to expose the gate contact region 26 on the active semiconductor layer 17.

Next the gate metal Schottky contact structure 28 is formed. Here the gate metal structure 28 forming process uses evaporation or sputtering in the following order: a layer molybdenum layer 28, here 3-8 nm thick, in Schottky contact with the active layer 17 followed by a Ti layer 30, here 30-50 nm thick, followed by Pt layer 32, here 30-80 nm thick, followed by gold layer 34, here 200-600 nm thick, as shown. The evaporation or sputtering processes are here at temperature in the range up to 300 degrees C.

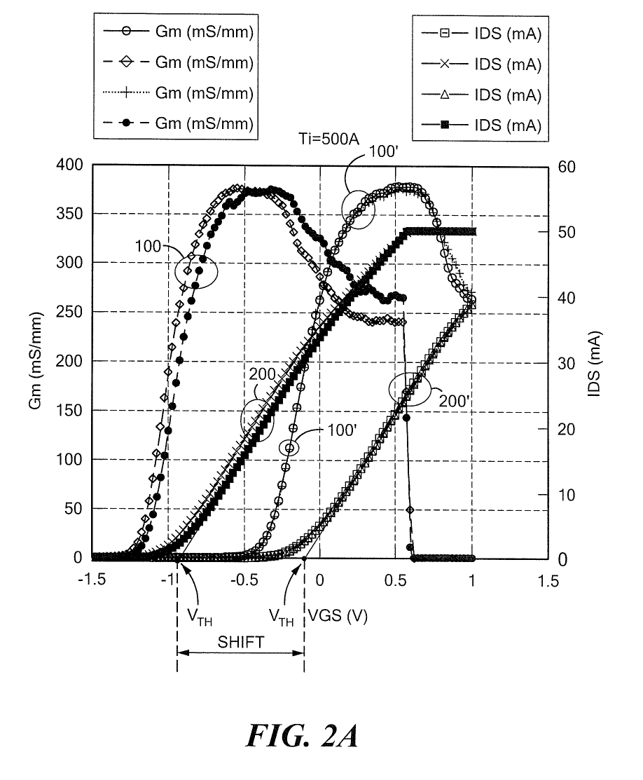

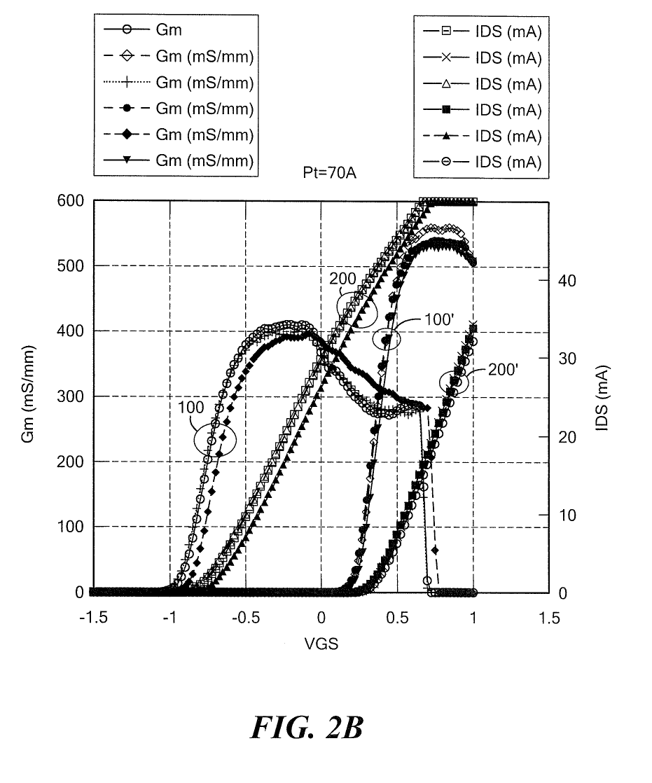

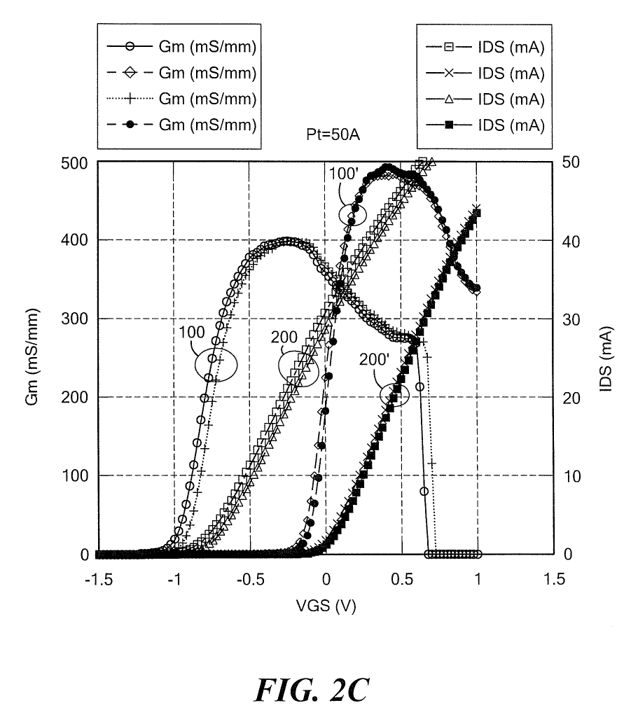

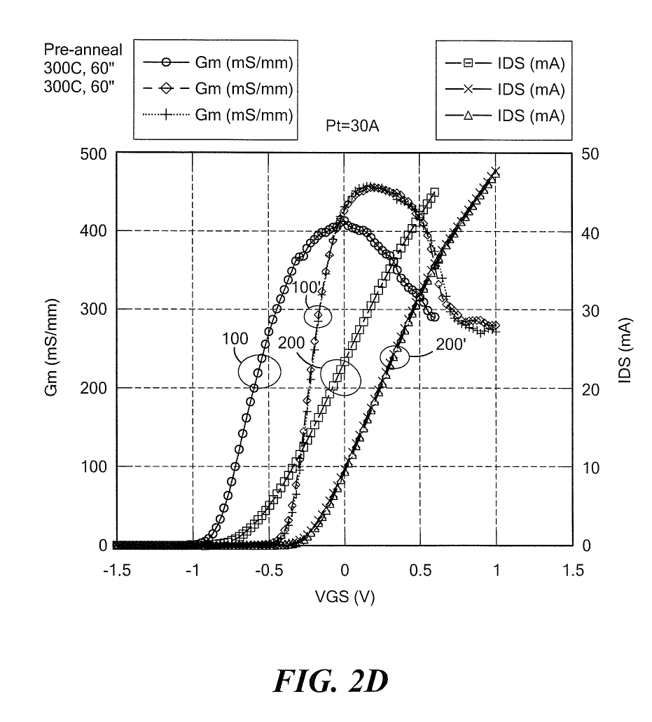

It is noted that in a typical integrated circuit fabrication process, additional elements would be formed on the substrate 10 in addition to the FET structure 10. These elements may for example include capacitors, resistors, air bridges and dielectric layers such as silicon nitride. Process temperatures used to form these elements may reach as high as 300 degrees C. With a FET structure having an Schottky contact of titanium, the effect of this processing changes the threshold voltage of the FET. This is shown in FIG. 2A where a FET structure having a 500 Angstroms thick titanium Schottky contact was annealed in an argon or nitrogen environment at a temperature of 300 degrees C. The curves labeled 100 shows the transconductance (gm) of a pair of FETs having a titanium Schottky contact prior of the anneal and the curves 100′ show the transconductance after the anneal. Note the shift in gate to source voltage (VGS). The curves labeled 200 shows the source to drain current (IDS) of the pair of FETs having a titanium Schottky contact prior of the anneal and the curves 200′ show the source to drain current (IDS) after the anneal. Again note the shift (SHIFT) in gate to source voltage (VGS).

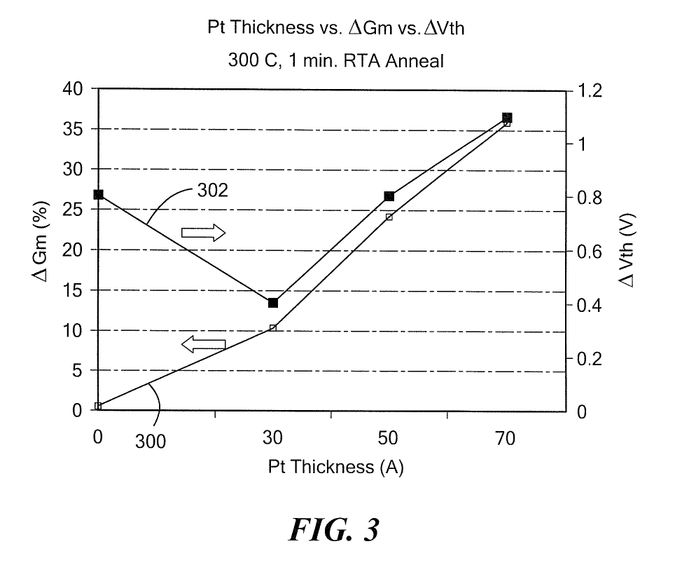

FIGS. 2B through 2D show similar curves for here with platinum, instead of molybdenum, as the Schottky contact layer (in contact with the InGaP layer 18. Then deposit Ti, Pt, Au) with thickness of 70, 50, and 30 Angstroms, respectively, are deposited successively of the platinum. Referring now to FIG. 3, curve 300 shows the change, ΔGm, in Gm and curve 302 shows the change, ΔVth, in threshold voltage (Vth) as a function of the thickness of the platinum Schottky contact.

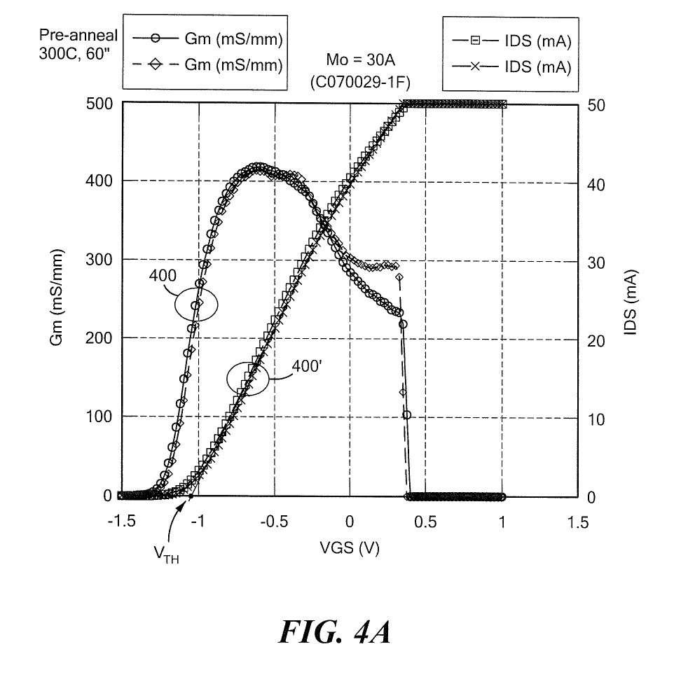

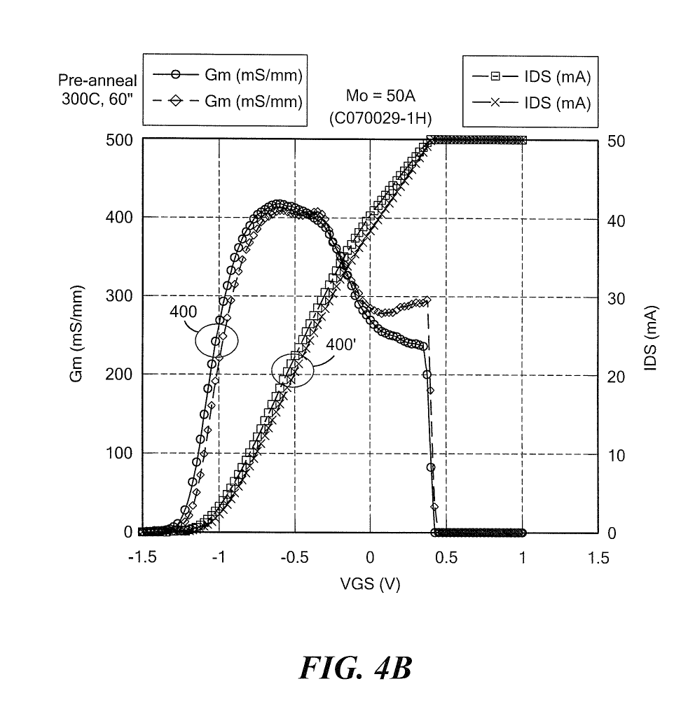

FIG. 4A show the FET structure 10 (FIG. 1) with a molybdenum layer 28 thickness of 30 Angstroms before and after an anneal. Here, curve 400 shows Gm as a function of the gate to source voltage (VGS) prior to the anneal and after a 60 second anneal at 300 degrees C, and cure 400′ shows IDS prior to the anneal and after a 60 second anneal at 300 degrees C. Note there is no shift in Vth after the 60 second anneal at 300 degrees because of the stability of the relatively thin (e.g., 30 Angstrom) molybdenum. FIG. 4B shows the effect under the same conditions for a FET having a molybdenum layer 28 thicknesses of 50 Angstroms.

A number of embodiments of the invention have been described. Nevertheless, it will be understood that various modifications may be made without departing from the spirit and scope of the invention. Accordingly, other embodiments are within the scope of the following claims.

What is claimed is:

1. A semiconductor structure comprising:
a semiconductor comprising a Indium Gallium Phosphide;
a molybdenum metal in Schottky contact with the semiconductor.

2. The semiconductor structure recited in claim 1 including an electrically conductive metal on the molybdenum metal.

3. The semiconductor structure recited in claim 2 wherein the electrically conductive metal comprises titanium on the molybdenum metal, platinum on the titanium, and gold on the platinum.

4. A semiconductor structure comprising:
an InGaP semiconductor;
a molybdenum metal in Schottky contact with the semiconductor.

5. The semiconductor structure recited in claim 4 including an electrically conductive metal on the molybdenum metal.

6. The semiconductor structure recited in claim 5 wherein the electrically conductive metal comprises titanium on the molybdenum metal, platinum on the titanium, and gold on the platinum.

7. A transistor, comprising:
a semiconductor comprising InGaP;
a gate electrode, such gate electrode comprising a molybdenum metal in Schottky contact with the semiconductor.

8. The transistor recited in claim 7 including an electrically conductive metal on the molybdenum metal.

9. The transistor recited in claim 8 wherein the electrically conductive metal comprises titanium on the molybdenum metal, platinum on the titanium, and gold on the platinum.
